(19) United States
(12) Patent Application Publication
(10) Pub. No.: US 2008/0297869 A1
(43) Pub. Date: Dec. 4, 2008

(54) OSCILLATOR DEVICE AND DRIVE CONTROL METHOD FOR OSCILLATION SYSTEM OF OSCILLATOR DEVICE

(75) Inventors: Takahiro Akiyama, Kawasaki-shi (JP); Kazunari Fujii, Kawasaki-shi (JP); Yukio Furukawa, Palo Alto, CA (US)

Correspondence Address: FITZPATRICK CELLA HARPER & SCINTO, 30 ROCKEFELLER PLAZA, NEW YORK, NY, 10112, US

(73) Assignee: CANON KABUSHIKI KAISHA, Tokyo (JP)

(21) Appl. No.: 12/132,780

(22) Filed: Jun. 4, 2008

(30) Foreign Application Priority Data
Jun. 4, 2007 (JP) 2007-148682

(51) Int. Cl. G02B 27/14; H03B 5/30

(52) U.S. Cl. 359/199; 331/154

(57) ABSTRACT

An oscillator device includes an oscillation system having at least one oscillator configured to oscillate, the oscillation system having a plurality of natural oscillation modes with a plurality of frequencies which frequencies are mutually in a relationship of integral-number ratio, a driving system configured to drive the at least one oscillation system, and a drive control system configured to control the driving system, wherein the drive control system applies to the driving system a driving signal in the form of a rectangular pulse based on combining a plurality of rectangular pulse signals corresponding to the plurality of natural oscillation modes, respectively.

### FIELD OF THE INVENTION AND RELATED ART

This invention relates to an oscillator device having oscillation system which includes at least one oscillator, and also to a drive control method for an oscillation system of an oscillator device. The oscillator device can be produced in accordance with a technique concerning a minute electric machine system (MEMS). When the surface of the oscillator is formed into a mirror surface, it can be applied as an optical deflector to optical equipments such as an image forming apparatus, e.g., an electrophotographic machine, or a visual display unit, e.g., a scanning display unit. Furthermore, the technique for drive-controlling an oscillation system including an oscillator is a component technique which constitutes feedback control of an ordinary oscillation system and a device for that purpose.

Today, rotary polygonal mirrors are used as an optical scanner for electrophotography. Studies and developments attempting electrophotographic exposure with use of an oscillatory type scanner have been conducted widely. On of them uses the aforementioned MEMS technique and produces a rotary polygonal mirror by etching a silicon wafer. The light scanningly deflected by a rotary polygonal mirror scans a photosensitive surface at a constant speed based on a correction optical system. On the other hand, the oscillation of the oscillator of the oscillatory type optical scanner is sine motion. Hence, the light scanningly deflected by this cannot directly produce constant-speed scan. In consideration of this, several methods have been proposed: a method of correcting an image signal which modulates scanning light during image drawing, a method of optically correcting the scanning light, and a method of scanningly deflecting light by using a plurality of scanners.

It is known that, if an oscillator is driven based on a driving signal in the form of a sum of a plurality of frequency components which are mutually in the relationship of integral multiple, the change with respect to time of the displacement angle of the oscillator takes approximately a chopping wave or sawtooth wave. There is an example (see U.S. Patent Application Publication No. US2006/0152785) wherein a driving signal based on the sum of a fundamental frequency component and a component of a double frequency is used, or an example (see U.S. Pat. No. 4,859,846) in which a driving signal based on the sum of a fundamental frequency component and a component of a triplication frequency is used. These examples realize a sawtooth wave or chopping wave by appropriately choosing the amplitude or phase of oscillation based on respective frequencies.

In order to apply the technique disclosed in U.S. Patent Application Publication No. US2006/0152785 or U.S. Pat. No. 4,859,846 to the electrophotographic process, it is necessary to use a drive control system which can very precisely control the amplitude and phase of the oscillatory type scanner having a natural oscillation mode with a plurality of natural oscillation frequencies which are in the relationship of integral multiple with respect to the same direction. In that case, if the waveform of the driving signal to be applied to the driving means for the oscillator, which is an actuator, is comprised of a sinusoidal wave, the drive control circuitry of the drive control system would be very complicated and expensive.

### SUMMARY OF THE INVENTION

The present invention provides an oscillator device by which inconveniences described above can be removed or reduced.

In accordance with an aspect of the present invention, there is provided an oscillator device, comprising: an oscillation system including at least one oscillator configured to oscillate, said oscillation system having a plurality of natural oscillation modes with a plurality of frequencies which are mutually in a relationship of integral-number ratio; driving means configured to drive said oscillation system; and drive control means configured to control said driving means; wherein said drive control means applies to said driving means a driving signal in the form of a rectangular pulse based on combining a plurality of rectangular pulse signals corresponding to said plurality of natural oscillation modes, respectively.

The drive control means may apply to said driving means a driving signal in the form of a rectangular pulse having an amplitude of binary or ternary value, based on combining the plurality of rectangular pulse signals.

The oscillation system may be configured to have a reference oscillation mode which is a natural oscillation mode having a reference frequency, and an integral-multiple oscillation mode which is a natural oscillation mode having a frequency which is n-fold the reference frequency where n is an integer.

The oscillation system may include a plurality of oscillators configured to oscillate, a plurality of torsion springs disposed along a co-axis coupling said plurality of oscillators in series, and a supporting member configured to support a portion of said plurality of torsion springs.

The oscillation system may include one oscillator configured to oscillate in circumferential directions about different axes.

The drive control means may apply to said driving means a driving signal of rectangular pulse having an amplitude of binary value based on combining the plurality of rectangular pulse signals, and the drive control means may apply to said driving means a driving signal having a frequency component sufficiently far away from a natural frequency when the amplitude should be made zero.

The drive control means may generate a plurality of rectangular pulse signals corresponding to sinusoidal waves having frequencies of the natural oscillation modes, respectively, while taking an amplitude, a pulse width and a phase difference of rectangular pulses of the rectangular pulse signals as parameters, wherein said drive control means may perform Fourier series expansion of a plurality of rectangular pulse signals as presented by the parameters and generates an equation including a sinusoidal wave by erasing a term of a frequency other than the frequency of the natural oscillation mode, among the terms expressed by the Fourier series expansion, to thereby determine the parameters based on the amplitude and phase of the equation, and said drive control means may drive the oscillation system in accordance with a driving signal which is based on the sum of the rectangular pulse signals determined by the parameters.

The oscillator device may further comprise detecting means configured to detect a state of oscillation of said oscillator.

The drive control means may calculate a controlled amount of the driving signal based on a signal from said detecting means and generates the driving signal.

In accordance with another aspect of the present invention, there is provided an optical deflecting device, comprising: a light source configured to generate a light beam; and an oscillator device as recited above and having a light deflecting element formed on said at least one oscillator.

In accordance with a still further aspect of the present invention, there is provided an optical equipment, comprising: an optical deflecting device as recited above; and a target object; wherein said optical deflecting device is configured to deflect light from said light source and to direct at least a portion of the light onto said target object.

In accordance with a yet further aspect of the present invention, there is provided a drive control method for an oscillation system including at least one oscillator configured to oscillate, the oscillation system having a plurality of natural oscillation modes with a plurality of frequencies which frequencies are mutually in a relationship of integral-number ratio, said method comprising: generating a plurality of rectangular pulse signals corresponding to sinusoidal waves having frequencies of the natural oscillation modes, respectively, while taking an amplitude, a pulse width and a phase difference of rectangular pulses of the rectangular pulse signals as parameters; performing Fourier series expansion of a plurality of rectangular pulse signals as presented by the parameters and generating an equation including a sinusoidal wave, by erasing a term of a frequency other than the frequency of the natural oscillation mode, among the terms expressed by the Fourier series expansion; determining the parameters based on the amplitude and phase of the equation; and driving the oscillation system in accordance with a driving signal which is based on the sum of the rectangular pulse signals determined by the parameters.

In accordance with the present invention, a driving signal in the form of a comparatively simple rectangular pulse may be generated and applied to driving means of the oscillation system. Hence, the structure of the drive control means for generating the driving signal can be comparatively simple. Moreover, since the oscillation system is structured to have a plurality of natural oscillation modes having frequencies which are mutually in the relationship of integral-number ratio, approximately only the component of the frequency of the natural oscillation mode of the driving signal having a rectangular pulse form can substantively activate the vibrational motion of the oscillation system. Therefore, by adjusting the rectangular pulse form based on some parameters to thereby adjust and control the component of the frequency of approximately natural oscillation mode toward the desired frequency component, the oscillator device such as an oscillatory type optical scanner can be controlled very accurately as desired based on a comparatively simple driving system. In this manner, the technique of drive control method for an oscillator device or an oscillation system according to the present invention can be applied to an image forming apparatus using electrophotographic technology or a visual display unit such as a scanning display unit, and a high-definition image can be formed thereby.

These and other objects, features and advantages of the present invention will become more apparent upon a consideration of the following description of the preferred embodiments of the present invention taken in conjunction with the accompanying drawings.

### BRIEF DESCRIPTION OF THE DRAWINGS

FIG. 1 is a schematic diagram which shows a first working example of the present invention.

FIG. 2 is a block diagram illustrating a basic form of an embodiment of the present invention.

FIG. 3 is a schematic diagram illustrating the control based on a rectangular wave of the present invention.

FIG. 4 is a diagram showing a rectangular wave, to explain the first working example of the present invention.

FIG. 5 is a diagram showing a driving waveform generated by the sum of rectangular waves illustrated in FIG. 4.

FIG. 6 is a diagram showing a rectangular wave, to explain a second working example of the present invention.

FIG. 7 is a diagram showing a driving waveform generated by the sum of rectangular waves illustrated in FIG. 6.

FIG. 8 is a schematic diagram showing a third working example of present invention.

FIG. 9 is a schematic diagram showing a fourth working example of the present invention.

FIG. 10 is a schematic diagram for explaining an image forming apparatus according to a fifth working example of the present invention.

### DESCRIPTION OF THE PREFERRED EMBODIMENTS

Preferred embodiments of the present invention will now be described with reference to the attached drawings.

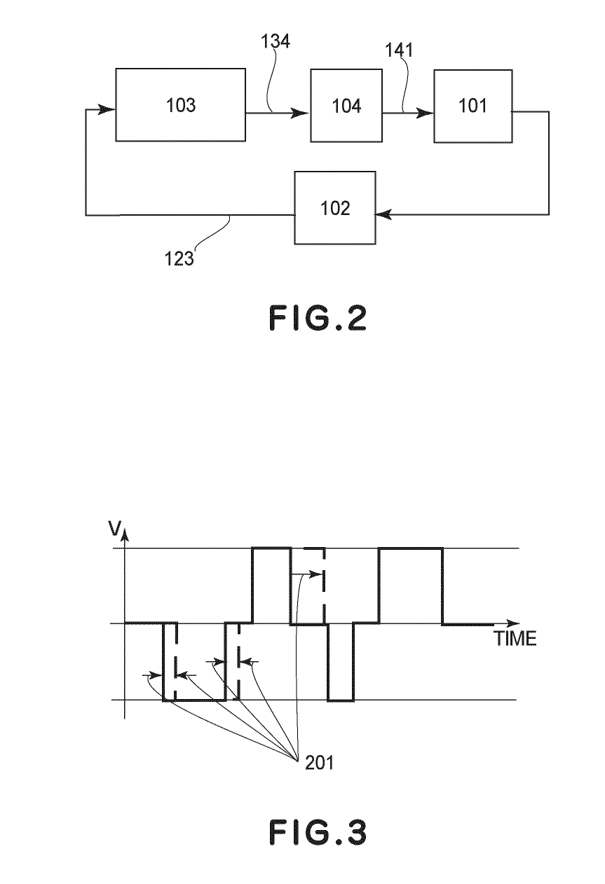

Now, an embodiment of oscillator device as well as a drive control method for an oscillation system of an oscillator device will be explained. FIG. 2 illustrates the outline of this embodiment of the present invention.

The drive control device of the present embodiment includes an oscillator 101 which is a controlled system, detecting means 102 for detecting displacement of the oscillator, drive control means 103 which outputs a driving signal 134 based on a signal 123 from the detecting means, and driving means 104 which is an actuator for moving the oscillator.

The oscillator 101 can be oscillated in natural oscillation modes of two frequencies which are mutually in the relationship of integral multiple (relationship of 1:n or m:n where m and n are natural numbers) in the same circumferential direction. The oscillation system including this oscillator is configured to have such natural oscillation mode. With this arrangement, in this oscillation system, if the oscillator 101 is resonance-driven, the change of the displacement thereof with respect to time takes a sinusoidal wave of the frequency of the natural oscillation mode. By combining the frequencies of the two components of the driving signal 134 and by adjusting parameters such as phase difference and amplitude, etc. thereof, the oscillator 101 can be moved in accordance with various waveforms.

The oscillator 101 of an oscillation system which includes at least one oscillator, can also be oscillated in plural modes which are mutually in the relationship of integral multiple in different directions. In such an oscillation system, if the oscillator 101 is resonance-driven, the change of the displacement thereof with respect to time takes a sinusoidal wave of the frequency of the natural oscillation mode, with regard to different directions. Even in this case, by combining the frequencies of the components of the driving signal and by adjusting parameters such as phase difference and amplitude, etc. thereof, the oscillator 101 can be moved in accordance with various waveforms.

Particularly, if the frequencies of two components of the driving signal and the natural oscillation frequency of the oscillation system including the oscillator 101 are close to each other, resonance motion will be provided. Therefore, the control input 141 to be applied by the driving means 104 to the oscillation system can be reduced. Thus, the driving efficiency increases.

On the other hand, if the ratio of two frequencies of the natural oscillation modes is approximately 1:2 or 1:3, by appropriately choosing the amplitude and phase, the oscillation waveform of the former can be nearly a sawtooth wave while the oscillation waveform of the latter can be nearly a chopping wave. This would be readily understood from the fact that the Fourier transform of the sawtooth wave corresponds to the sum of sinusoidal waves of the fundamental frequency and a frequency which is an integral multiple of the fundamental frequency, and that the Fourier transform of the chopping wave corresponds to the sum of sinusoidal waves of the fundamental frequency and a frequency which is n-fold the fundamental frequency where n is an odd integer.

The detecting means 102 is provided to detect displacement of the oscillator 101. However, it is not always necessary to detect all the displacements. It may detect only a particular displacement. However, in order to detect the state of the oscillator 101 which oscillates at different frequencies, a reasonable number of sample points will be necessary. For example, if it oscillates at two frequencies, displacements at least at two points should be detected. Therefore, the detecting means 102 in the present embodiment is configured to have a function for detecting displacement of the oscillator 101 at least at two points.

In response to the signal 123 from the detecting means 102, the drive control means 103 calculates the difference with reference to the signal which should be applied when the oscillator 101 is in the target oscillation state, and then it generates a driving signal 134 of rectangular wave with a controlled variable added thereto. In accordance with the present invention, the driving signal 134 is a rectangular pulse signal. Preferably, this driving rectangular wave 134 takes only a binary or ternary value, and by adjusting the rise time and fall time of the rectangular wave, the driving signal is controlled. With this arrangement, the structure of the drive control means 103 for generating the driving signal can be extremely simplified. FIG. 3 illustrates the concept of the control of the rectangular wave. This is an example wherein the driving rectangular wave 134 takes a ternary value. However, basically this is also the case with a binary value. As shown by an arrow 201, by shifting the rise time or fall time of the rectangular wave, the amplitude and phase of motion of the oscillator 101 can be controlled.

The drive control means 103 applies to the driving means 104 a rectangular pulse driving signal based on synthesizing two rectangular pulse signals corresponding to the two natural oscillation modes each to driving means 104. Hence, by combining frequencies of two components of the driving signal 134 and by adjusting parameters such as phase difference and amplitude thereof, for example, oscillator 101 can be oscillated in accordance with various waveforms.

The drive control process for the oscillation system made by the drive control means 103 can be summarized as follows.

Two rectangular pulse signals corresponding to sinusoidal waves having frequencies of two natural oscillation modes by which a target oscillation state can be realized in the oscillation system are generated. Here, the amplitude and pulse duration of the rectangular pulse of each rectangular pulse signal as well as the phase difference (deviation of the rectangular pulse center from the time phase whereat a corresponding sinusoidal wave shows an extreme value) are taken as parameters. Since the two frequencies have an integral-number ratio, rectangular pulse signals corresponding to the periods of there integral numbers, respectively, should be generated. For example, if the ratio is 1:2, one pulse signal should have only one period while the other signal should have only two periods. If the ratio is 2:3, one should have only two periods while the other should have only three periods. Preferably, these rectangular pulse signals should be adjusted so that a combined rectangular pulse signal based on synthesizing two rectangular pulse signals take an amplitude value of binary or ternary value. Therefore, if this condition should not be satisfied, corresponding one of the pulses of the rectangular pulse signal may be deleted.

The thus generated two rectangular pulse signals are synthesized. Here, the plurality of rectangular pulse signals being expressed by the parameters are Fourier-series developed, while on the other hand terms of frequencies other than the frequency of the natural oscillation mode, among the terms presented by the Fourier series expansion, are erased by which an equation including a sinusoidal wave is generated. Then, based on the amplitude and phase of this equation, target values of the amplitude, pulse width and phase difference which are parameters of the rectangular pulse signal are determined. In this manner, a rectangular pulse driving signal based on synthesizing two rectangular pulse signals is determined. Then, the drive control means 103 generates such a signal and applies it to the driving means 104. The reason why the terms of frequencies other than the frequencies of two natural oscillation modes can be erased is that the oscillation of the oscillation system is hardly excited by a driving signal of such component having a frequency other than the frequencies of the two natural oscillation modes. In other words, applying the rectangular pulse driving signal as described above to the driving means is equivalent in effect to that a driving signal based on combining sinusoidal waves having frequencies of the two natural oscillation modes is applied to the driving means 104.

As a result of the procedure described above, the state of oscillation caused in the oscillation system is detected by the detecting means 102. Based on this detection result, the drive control means 103 adjusts the rectangular pulse driving signal and feedback controls the state of oscillation of the oscillation system. Generating such a rectangular pulse driving signal described above is easier than just generating sinusoidal signal. For example, it can be done by a structure using a simple power source and switching means. Among them, it is particularly easy to generate a rectangular pulse driving signal having an amplitude value of binary or ternary value.

The driving means 104 is able to apply a driving force to the oscillation system based on an electromagnetic system having a driving coil and a magnet, an electrostatic system or a piezoelectric system. In the case of electrostatic driving, an electrode may be formed on at least one oscillator, while another electrode effective to produce an electrostatic force acting between these electrodes may be formed in the vicinity of the oscillator. In the case of piezoelectric driving, a piezoelectric element may be provided at the oscillation system or a supporting member, and a driving force is applied.

The detecting means 102 can be constituted using a light receiving element or a piezoresistor. If the displacement angle of the oscillator is detected using a piezoresistor, as an example the piezoresistor may be provided at a torsion spring, and the time moment whereat the oscillator takes a certain displacement angle may be detected based on a signal output from this piezoresistor. The piezoresistor can be manufactured by, for example, scattering phosphor in p-type monocrystal silicon. The piezoresistor produces a signal depending on the torsion angle of the torsion spring. Thus, if the displacement angle of the oscillator is to be measured, piezoresistors may be provided at a plurality of torsion springs, and the displacement angle of the oscillator may be detected based on information of the torsion angle of the plurality of torsion springs. Then, the displacement angle can be measured very precisely.

In accordance with the present embodiment, since a driving signal in the form of a comparatively simple rectangular pulse is generated and applied to the driving means 104 of the oscillation system. Hence, the structure of the drive control means 103 for generating the driving signal can be made comparatively simple.

### WORKING EXAMPLES

Several working examples of oscillator device and drive control method of an oscillation system thereof will be explained below with reference to the drawings.

### Working Example 1

A first working example of the present invention will now be explained. The conception diagram of this example is the same as one shown in FIG. 2, having been described with reference to the preceding embodiment.

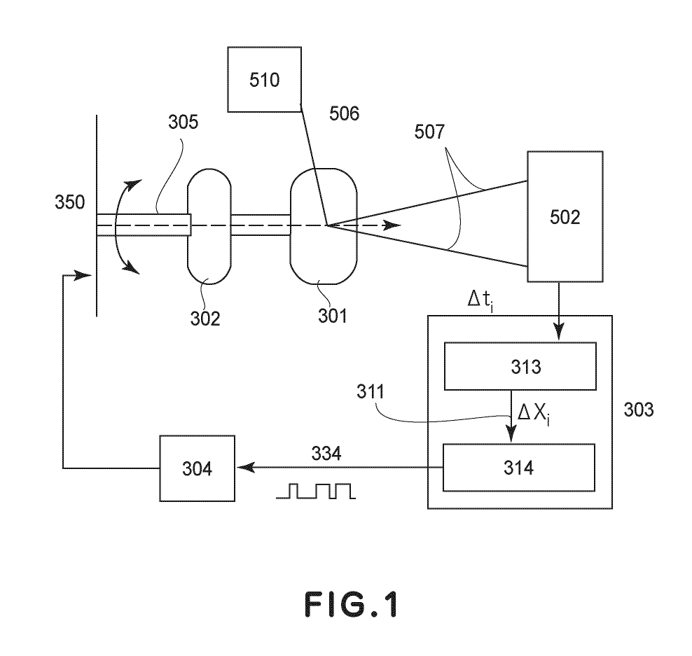

The structure of this working example is shown in FIG. 1. In the structure of FIG. 1, the oscillation system includes a plurality of oscillators 301 and 302 which can oscillate, a plurality of torsion springs disposed along a co-axis (oscillation axis 305) coupling a plurality of oscillators in series, and a supporting member 350 for supporting a portion of the plurality of torsion springs. The oscillation system is configured to have two natural oscillation modes having natural frequencies which are mutually in the relationship of integral-number ratio, in the circumferential direction around the same axis. Typically, it is configured to have a fundamental oscillation mode which is a natural oscillation mode of fundamental frequency as well as an integral-multiple oscillation mode which is a natural oscillation mode of a frequency n-fold the fundamental frequency where n is an integer.

In the structure of FIG. 1, an output light beam 506 from a light source 510 impinges on an optical reflection surface of the oscillator 301 of the oscillation system and it is scanningly deflected, whereby scanning light 507 is provided. The scanning light 507 is projected on the detecting means 502 as well as a target object such as a photosensitive member or a display member. In this working example, as the detecting means, optical detection means 502 which is configured to detect two points on the scan line of the scanning light 507 is provided. A photodetector may be used as this optical detection means 502, for example. Two such photodetectors may be provided or, alternatively, only one may be provided and the scanning light 507 at two points may be detected using an optical system. Furthermore, without using optical detection means, if a sensor which is able to detect the displacement angle of the oscillator 301 at two points is available, it may be used. In this working example, point-measurement optical detection means is used.

In this manner, the state of oscillation caused in the oscillation system is detected through the optical detection means 502. Based on the detection result, the drive control means 303 adjusts and controls the driving signal 334 in the form of rectangular pulse, and a resultant signal is applied to the driving means 304 which is an actuator. The driving means 304 drives the oscillation system in accordance with the thus applied driving signal. The drive control means 303 comprises an arithmetic logical unit 313 for calculating the difference 311 with respect to the target amplitude/phase in the oscillation state, and a control unit 314 for generating the pulse waveforms.

Next, while explaining the principle of drive control in this working example, the operation will be explained.

If the displacement angle detected by the optical detection means 502 is smaller than the amplitude of the oscillator 301 (namely, the maximum displacement angle thereof) and the harmonics component of the oscillation is small, this optical detection means 50 produces an output four times per one oscillation period. The time moments whereat these four outputs are produced sequentially are denoted by t1, t2, t3 and t4, respectively.

The motion of the oscillator 301 being driven while including two frequency components which are mutually in an integral-number ratio of 1:n can be depicted by equation (1) below.

q=A1 sin(ωt+f1)+A2 sin(nωt+f2) (1)

wherein A1 and A2 are amplitude, f1 and f2 are phase, n an integral number, and omega is angular frequency. The angular frequency ω is approximately equal to the product of the natural oscillation frequency of the oscillator 301 in the circumferential direction around the oscillation axis 305 with 2π. The target amplitude and phase of the oscillation of the oscillator 301 are denoted by A10, A20, f10 and f20, and the target time whereat the optical detection means 502 produces an output is denoted by t10, t20, t30 and t40. Then, with regard to the amplitude and phase and these four time moments, since the amplitude and phase are determined definitely around the target amplitude and phase, a transformation equation such as equation (2) below applies.

{A1−A10,A2−A20,f1−f10,f2−f20}^{T}=M*{t1−t10,t2−t20,t3−t30,t4−t40}^{T} (2)

wherein M is the matrix of 4×4 and it is determined based on the displacement of oscillation detected by the optical detection means 502 and the driving frequency as well as the target amplitude and phase of the oscillator 301. Since generally all of these take fixed values, M is a constant matrix.

M can be expressed by equation (3) below in accordance with tensor notation, and this can be derived from equation (1).

Mij=(∂ti/∂xj)⁻¹, xj=A10,A20,f10,f20;

ti=t10,t20,t30,t40 (3)

If there is no inverse matrix, the difference 311 with respect to the target amplitude and phase of the oscillator 301 cannot be calculated. Therefore, the matrix M has to be regular. Since this is determined by the displacement angle of the oscillator 301 detected by the optical detection means 502, the optical detection means 502 is so set as to detect the displacement angle by which the matrix M can be regular.

Time t1, t2, t3, t4, t10, t20, t30 and t40 are converted into relative time with reference to t1. Here, the motion of the oscillator 301 is now defined by equation (4) below.

q=A1 sin(ωt)+A2 sin(nωt+f) (4)

Here, three variables of two amplitudes and one phase are presented.

If the time when the optical detection means 502 outputs a signal is re-defined as {t1−t1, t2−t1, t3−t1, t4−t1} [symbol] {0, t2−t1, t3−t1, t4−t1} in terms of the time interval from t1, the aforementioned transformation formula can be expressed as equation (5) below.

{A1−A10,A2−A20,f−f0}=M*{t2−(t20−t1),t3−(t30−t1),t4−(t40−t1)^{T} (5)

The transformation matrix Mij can be expressed as equation (6) below.

Mij=(∂ti/∂xj−∂t10/∂xj)⁻¹, xj=A10,A20,f0;

ti=t20,t30,t40 (6)

This is 3*3 regular and yet constant matrix.

In this manner, based on the output signal from the optical detection means 502, the difference 311 with respect to the target amplitude and phase is calculated. Hence, {t20,t30,t40}^{T} is obtained as the control object.

If the driving signal of sinusoidal wave is to be inputted into the control means 304 which is an actuator, to perform the drive, the driving signal waveform V can be presented by equation (7) below.

V=V1 sin(ωt)+V2 sin(nωt+y) (7)

Here, in order to bring the oscillator 301 come close to the target amplitude and phase {A10, A20, f0}, as a controlled variable, the product of difference 311 with respect to the target amplitude and phase by the coefficient {k1, k2, l1} is added to the driving waveform, and the resultant is applied to the driving means 304. Namely, V′ as can be expressed by equations (8) and (9) below is inputted into the driving means 304.

V′=V1′ sin(ωt)+V2′ sin(nωt+y′) (8)

{V1′,V2′,y′^{T}={V1+k1*(A1−A10),V2+k2*(A2−A20),y+1*(f−f0)}^{T} (9)

where V1 and V2 are input wave amplitude of the driving signal to be applied to the actuator 304, and y is phase.

As described above, the difference 311 is calculated by equation (5) using the time interval of the signal outputted from the optical detection means 502, and a driving waveform generated based on this result and in accordance with equations (8) and (9) is inputted into the driving means 304. By repeating such detection and the adjustment and control of the driving waveform described hereinbefore, the state of oscillation of the oscillator 301 is controlled toward the target amplitude and phase.

Although the foregoing description has been made with reference to the process of generating a driving signal in the form of the sum of sinusoidal waves and applying the same to the driving means 304, in this working example of the present invention, a driving signal of rectangular pulse form which is easy to generate is generated. Since the oscillation system including the oscillator 301 is configured to have two natural oscillation modes, if a rectangular wave is inputted into the actuator 304 to drive the same, only the basis function of the fundamental frequency of the Fourier series of the rectangular wave and the component of the n-fold higher harmonic function should be taken into account. The reason for this is that, since the oscillator 301 is resonance oscillated as described hereinbefore, the effect to be provided to the resonance motion of the frequency component of oscillation different from the frequency of natural oscillation mode becomes substantially zero. Hereinafter, a case of n=2 will be explained as an example.

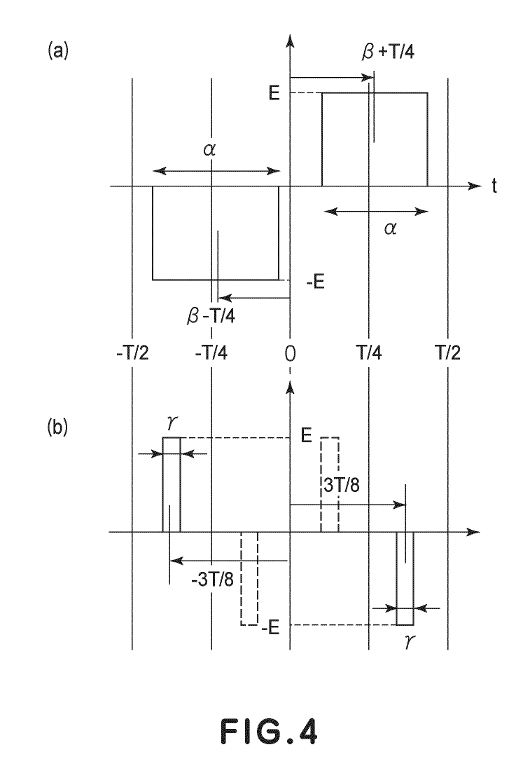

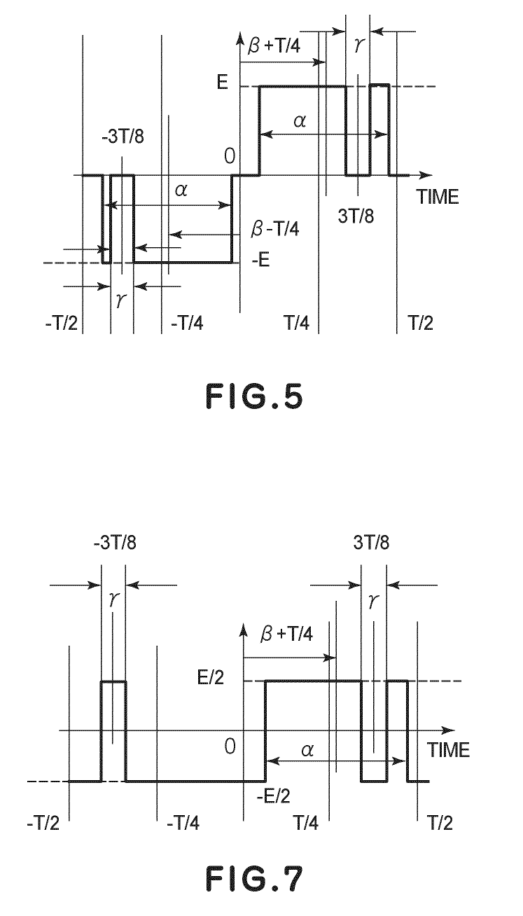

FIG. 5 shows the waveform of the driving signal which the drive control means 303 inputs into the actuator 304. This is an example of the driving input waveform, and this driving signal waveform is produced by adding up the two rectangular waves shown in FIG. 4. Namely, the rectangular wave shown in part (a) of FIG. 4 has a fundamental frequency, while the rectangular wave shown in part (b) of FIG. 4 has a frequency n-fold higher harmonic. In FIG. 4, denoted at E is the amplitude of the rectangular wave, and denoted at T is the period of the fundamental frequency. Denoted at α and γ are the widths of the rectangular waves, and denoted at β is the deviated time of the center of the rectangular wave having a width α, from the time phase whereat the corresponding sinusoidal wave shows an extreme value. Here, in order to assure that the driving signal waveform based on the adding up mentioned above takes only a ternary value, those portions of rectangular waves of FIG. 4, part (b), as depicted by broken lines are not added up. Here, since the frequency of the rectangular wave of FIG. 4, part (a) and the frequency of the rectangular wave of FIG. 4, part (b), are in the relationship of 1:2, the waveform is generated only in the time unit shown in FIG. 4 and FIG. 5, and the remainder can be given by repeating this.

The sum of the basis function component and n-fold harmonics component of the Fourier series of the rectangular signal waveforms formed in this way and the sinusoidal signal waveform given by equation (7) should be equal to each other. Thus, these relationships are presented by equation (10) below.

$$V = P sin ω t + Q cos ω t + R sin 2 ω t \\ P = \frac{4 E}{π} sin ( \frac{α π}{T} ) cos ( \frac{2 β π}{T} ) - \frac{2 \sqrt{2} E}{π} sin ( \frac{γ π}{T} ) \\ Q = - \frac{4 E}{π} sin ( \frac{α π}{T} ) sin ( \frac{2 β π}{T} ) \\ R = \frac{2 R}{π} sin ( \frac{2 γ π}{T} ) \qquad ( 10 )$$

The relationship of α, β and γ with P, Q and R is the same as described above. Equation (7) and equation (10) when n=2 are mathematically equivalent to each other, although the form is different.

If a driving signal of sinusoidal wave is used, V′ which is expressed by equations (8) and (9) is inputted into the driving means 304 so as to bring the oscillator 301 come close to the state of target oscillation. On the other hand, if a driving signal of rectangular signal waveforms is used, the following steps are taken. From equation (7) through equation (10), P0, Q0 and R0 which are P, Q and R of the target are detectable and, furthermore, α0, β0 and γ0 which are α, β and γ of the target are detectable. Namely, P0, Q0 and R0 are target values of the amplitudes when the signal to be inputted to the actuator 304 has a sinusoidal wave, and these are detectable from the target amplitude and phase of the oscillator 301. Furthermore, from these, α0, β0 and γ0 are detectable. Hence, based on the detection signal, α, β and γ which determine the width and deviation time of this rectangular wave are adjusted, whereby the oscillator 301 can be adjusted and controlled toward the target motion.

As described above, from equation (8) and the like, P0, Q0 and R0 which are P, Q and R of the target are detectable. Furthermore, from equation (10), α0, β0 and γ0 which are α, β and γ of the target are detectable. There is a regular transformation matrix Lij between {a−a0,b−b0,g−g0} and {P−P0,Q−Q0,R−R0} as well. This can be expressed by equation (11) below.

{a−a0,b−b0,g−g0}^{T}=Lᵢⱼ*{P−P0,Q−Q0,R−R0}^{T}

Lij=(∂Hi/∂ηj)⁻¹, Hi=P,Q,R; ηj=α,β,γ (11)

If {a0,b0,g0} is substituted into {a,b,g}, then Lij will be a constant matrix. In this manner, the difference 311 is calculated by equation (5) based on the time interval of the signal outputted from the optical detection means 502 and, by using this result, pulse waveforms generated in accordance with equations (8) through (10) and (11) are inputted into the actuator 304. By repeating this, the oscillator 301 can be adjusted and controlled into the state of oscillation having target amplitude and phase.

Since both Mij and Lij are a constant and yet a regular matrix, as described above, practically the controlled variable can be calculated from the aforementioned time interval. Thus, in FIG. 1, the difference 311 with respect to the target amplitude and phase is calculated by the arithmetic logical unit 313 inside the drive control means 303, and the pulse waveforms are generated by the control unit 314. However, this can be modified as follows. Namely, the pulse waveform can be calculated and generated, in practice, without calculating the difference 311 with respect to the target amplitude and phase.

Furthermore, although only ternary values of E, 0 and −E are taken as shown in FIG. 5 when the rectangular waves of FIG. 4 are added up, the zero value can be realized in the following manner.

When it is zero, E and −E are alternately applied using a frequency irrelevant to the frequency of the driving signal (i.e., a frequency sufficiently spaced apart from the natural oscillation frequency), by which the input signal to the actuator 304 can take only a binary value. Here, the frequency sufficiently spaced apart from the natural oscillation frequency means such frequency that does not have an influence on the oscillation state of the oscillation system even if the oscillation system is driven. For example, it may be a portion around the bottom of the peak of the resonance frequency of the oscillation system.

The waveform generating member of the control unit 314 which outputs rectangular waves having been described above can be designed by using a switching circuit of H bridge type, for example. This is a comparatively simple structure. In this manner, in accordance with this working example of the present invention, the oscillation system can be drive controlled by a comparatively simple structure.

### Working Example 2

A second working example of the present invention will be explained below. The concept of this working example is similar to that shown in FIG. 2. As shown in FIG. 1, like the first example, the present working example comprises an oscillation system including two oscillators 301 and 302 which oscillate in a circumferential direction around an oscillation axis 305. The structure as a whole of this working example is similar to the first embodiment as well. This working example is a modified form of the first example, and it differs from the first in that, in this example, the rectangular wave to be applied by the drive control means 303 into the actuator 304 takes only a binary value.

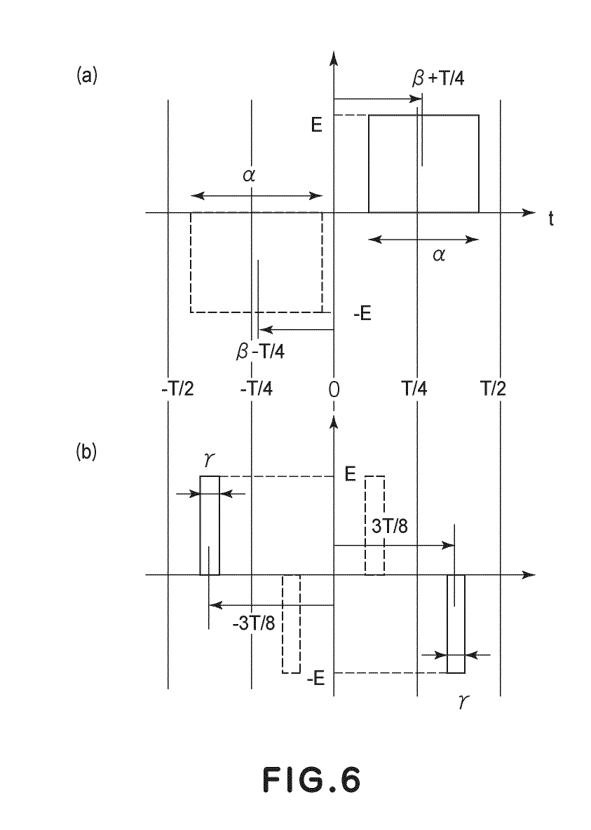

FIG. 7 shows the signal in the form of a rectangular pulse, which the drive control means 303 inputs into the actuator 304. This is an example of input waveform of the driving signal. The driving waveform of FIG. 7 can be produced by adding up the two rectangular waves shown in FIG. 6 and thereafter by upwardly shifting the zero point on the axis of ordinate by E/2. Namely, the rectangular wave shown in part (a) of FIG. 6 has a fundamental frequency, while the rectangular wave shown in part (b) of FIG. 6 has a frequency n-fold higher harmonic. In FIG. 6, denoted at E is a value which is twofold the amplitude that the rectangular wave of FIG. 7 can take, and denoted at T is the period of the fundamental frequency. Denoted at α and γ are the widths of the rectangular waves shown in FIG. 6, part (a) and part (b), respectively, and denoted at β is the deviated time of the center of the rectangular wave having a width α. Here, in order to assure that the driving signal waveform based on the adding up mentioned above takes only a binary value, those portions of rectangular waves of FIG. 6, part (a) and part (b), as depicted by broken lines are not added up. In this example as well, the waveform is generated only in the time unit shown in FIG. 6 and FIG. 7, and the remainder can be given by repeating this.

In this example as well, the sum of the basis function component and n-fold harmonics component of the Fourier series of the rectangular signal waveforms formed in this way and the sinusoidal signal waveform given by equation (7) should be equal to each other. Thus, these relationships are presented by equation (12) below.

$$V = a 0 / 2 - D sin ω t - F cos ω t + G sin 2 ω t \\ D = \frac{E}{π} sin ( \frac{α π}{T} ) cos ( \frac{2 β π}{T} ) - \frac{\sqrt{2} E}{π} sin ( \frac{γ π}{T} ) \\ F = - \frac{E}{π} sin ( \frac{α π}{T} ) sin ( \frac{2 β π}{T} ) \\ G = \frac{E}{π} sin ( \frac{2 γ π}{T} ) \\ \frac{a 0}{2} = E * ( α - \frac{T}{2} ) \qquad ( 12 )$$

The relationship of α, β and γ with D, F, G and a0 is the same as described above. The principle of drive control is the same as the first example. However, in this working example, in order to erase the offset a0/2, such a waveform having a frequency sufficiently spaced apart from the natural oscillation frequency and making the time average equal to zero is taken as the input waveform. Alternatively, in the waveform of FIG. 7, for example, since the difference between the length of a half period T/2 and α is proportional to the offset a0/2, the adjustment of this difference may be performed by inserting a constant value once per several periods, to thereby erase the offset.

In this example as well, D, F and G are determined by adjusting α, β and γ which are parameters of the rectangular wave. As described above, for the control toward D0, F0 and G0 which are D, F and G of the target, α, β and γ which determine the width and deviation time of the aforementioned rectangular wave based on the detection signal, are adjusted to thereby adjust and control the oscillator 301 toward the state of oscillation having A10, A20 and f0 of the target. The manner of determination or adjustment and control process are similar to those of the first working example. In this working example as well, the oscillation system can be drive controlled by a comparatively simple structure.

### Working Example 3

A third working example of the present invention will be explained. The concept of this example is similar to that shown in FIG. 2, having been described with reference to the preceding example.

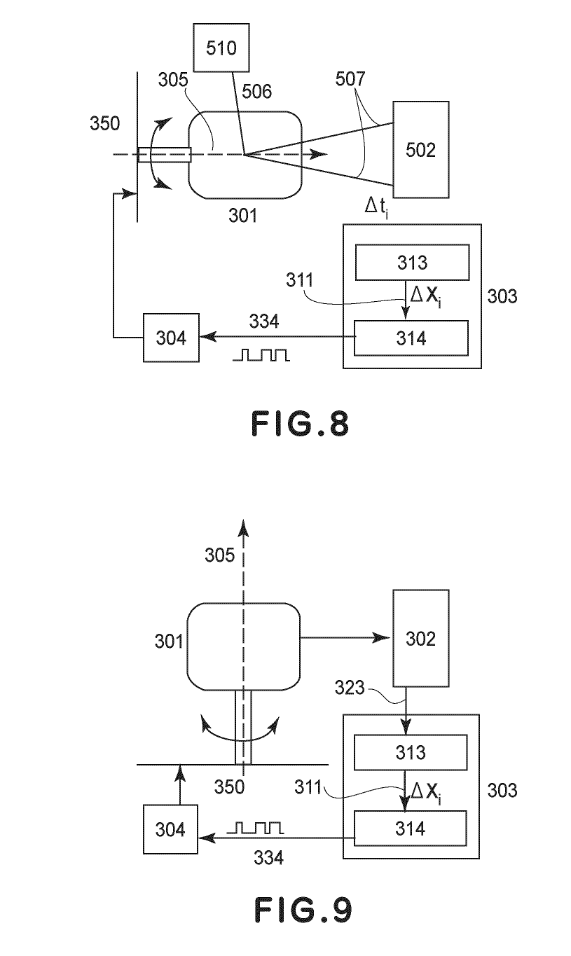

The structure of the third working example is illustrated in FIG. 8. In the structure of FIG. 8, the oscillation system includes a single oscillator 301 which is configured to oscillate in circumferential directions about different rotational axes, relative to the supporting member 350. Namely, the oscillation system has two natural oscillation modes in the circumferential directions about different axes. Here, one of the axes is an oscillation axis 305, and the other axis is an axis contained in the sheet of the drawing and being orthogonal to the oscillation axis 305.

In the structure of FIG. 8 as well, an output light beam 506 from a light source 510 impinges on the optical reflection surface of the oscillator 301 of the oscillation system, by which it is scanningly deflected and scanning light 507 is provided. In this working example as well, as a detecting means, optical detection means 502 which is able to detect two points on the scan line of the scanning light 507 is used.

In this working example as well, a driving signal in the form of rectangle pulse which is easy to generate is generated in accordance with the method having been explained with reference to the first or second example, and the oscillation system is drive controlled. The remaining points are essentially the same as the preceding examples.

### Working Example 4

A fourth working example of the present invention will be explained. The concept of this example is the same as one shown in FIG. 2, having been explained with reference to the preceding examples.

FIG. 9 is a schematic diagram showing a specific structure of this example. The oscillator 301 oscillates about the oscillation axis 305. In this working example, the displacement angle detecting means 302 which is detecting means may be built in the oscillator 301 or it may be an external sensor. In the latter case, the displacement angle detecting means may be a photodetector. In this example as well, one surface of the oscillator 301 is finished into an optical reflection surface and, by projecting light thereto, the light is scanningly deflected. By detecting the scanningly deflected light by use of the displacement angle detecting means 302, the displacement angle of the oscillator 301 can be detected.

The structure of the oscillator 301 may be one according to any of the preceding examples, or it may be a different one. As an example, the oscillator 301 includes a plurality of oscillators and a torsion spring disposed on the same oscillation axis coupling the oscillators in series. Furthermore, it may have a structure in which, as shown in the aforementioned U.S. Patent Application Publication No. US2006/0152785, one oscillator is surrounded or partly surrounded by another oscillator. Furthermore, although in FIG. 9 only one supporting member 350 is illustrated, there may be another supporting member at the other end portion. Namely, the structure in which the oscillator 301 is supported at two points on the oscillation axis 305, may be used.

In this working example as well, the drive control means 303 includes an arithmetic logical unit 313 for calculating the difference 311 with respect to the target amplitude and phase of the oscillator 301 from the signal 323 of the displacement angle detecting means 302, and a control unit 314 for generating a driving rectangular signal 334 which having a controlled variable added thereto from the difference. Here, like the first example, the driving rectangular signal 334 can be generated directly without calculating the difference 311 with respect to the target amplitude and phase. Furthermore, the thus generated driving rectangular signal 334 may take only a binary or ternary value. Therefore, by controlling the rise time and fall time of the driving rectangular signal 334, the pulse duration and pulse position are controlled and hence the amplitude and phase of the oscillation state of the oscillation system are controlled. In this working example as well, a driving signal in the form of rectangle pulse which is easy to generate is generated in accordance with the method having been explained with reference to the first or second working example, and drive control of the oscillation system is performed.

The oscillator 301, displacement angle detecting means 302, drive control means 303, driving means 304, signal 323 and driving rectangular signal 334 correspond to the oscillator 101 of FIG. 2, detecting means 102, drive control means 103, driving means 104, signal 123 and driving rectangular signal 134. Such correspondence mentioned above similarly applies to the preceding examples. The remaining points are similar to the preceding examples.

### Working Example 5

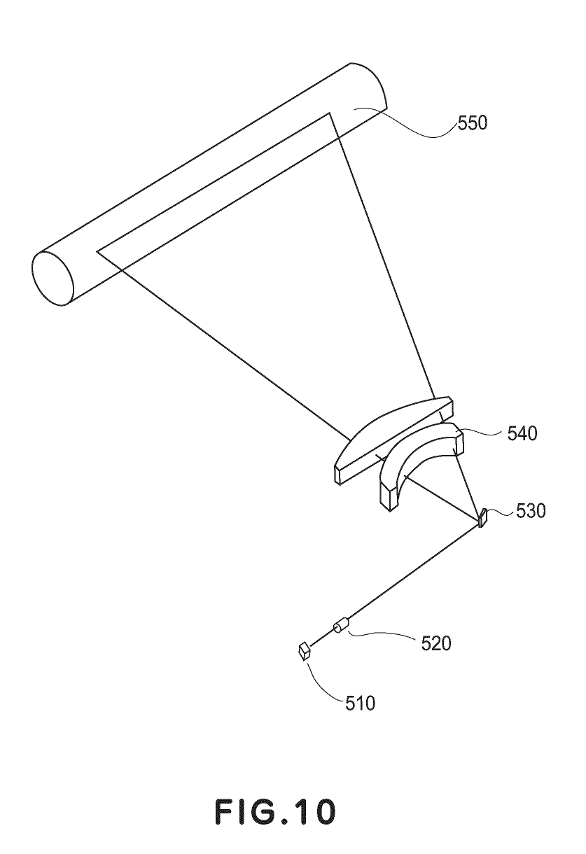

A fifth working example of the present invention will be explained. This is an example wherein a drive control device of an oscillator of the present invention is applied to an image forming apparatus which is one of optical equipments. The structure of this working example is illustrated in FIG. 10.

The ratio of two natural frequencies of the oscillation system of the oscillator device 530 is in the relationship of approximately 1:2 or 1:3. By controlling the amplitude and phase appropriately, the oscillator device 530 constituting the optical deflecting device provides oscillation close to a sawtooth wave when the natural frequency ratio is approximately 1:2 and provides oscillation close to a chopping wave when the ratio is approximately 1:3. Here, in some zones of one oscillation period, the speed comes close to constant angular-speed. Furthermore, the surface of the oscillator (not shown) of the oscillator device 530 is finished into an optical reflection surface. The light emitted from a light source 510 is shaped by a collimator lens 520, and then it is scanned by the oscillator device 530. The scanning light passes through a coupling lens 540 and it is imaged on a photosensitive drum 550, whereby the photosensitive drum 550 is exposed. By modulating the output light from the light source 510, an electrostatic latent image corresponding to the modulating signal is formed on the photosensitive drum 550.

The photosensitive member 550 being rotated around a rotation axis and in a direction perpendicular to the scan direction is electrostatically charged by a charging device (not shown) uniformly. By scanning this surface with light, an electrostatic latent image is formed on the scanned portion. Subsequently, a toner image is formed at the imagewise portion of the electrostatic latent image, by using a developing device (not shown). The toner image is then transferred to and fixed on a paper sheet (not shown), for example, an image is formed thereon.

In the image forming apparatus of the present invention using an oscillator device of comparatively simple structure according to the present invention, the optical scanning characteristic is improved, such that an image forming apparatus which produces a sharp image is accomplished.

An optical deflecting device of the present invention, comprising a light source for producing a light beam and an oscillator device having an optical deflection device for deflecting a light beam toward an oscillator, can be applied to a visual display unit. In that occasion, the visual display unit may comprise an image display member, and the optical deflecting device deflects the light from a light source and directs at least a portion of the light to the image display member.

While the invention has been described with reference to the structures disclosed herein, it is not confined to the details set forth and this application is intended to cover such modifications or changes as may come within the purposes of the improvements or the scope of the following claims.

This application claims priority from Japanese Patent Application No. 2007-148682 filed Jun. 4, 2007, for which is hereby incorporated by reference.

What is claimed is:

1. An oscillator device, comprising:
an oscillation system including at least one oscillator configured to oscillate, said oscillation system having a plurality of natural oscillation modes with a plurality of frequencies which are mutually in a relationship of integral-number ratio;
driving means configured to drive said oscillation system; and
drive control means configured to control said driving means;
wherein said drive control means applies to said driving means a driving signal in the form of a rectangular pulse based on combining a plurality of rectangular pulse signals corresponding to said plurality of natural oscillation modes, respectively.

2. An oscillator device according to claim 1, wherein said drive control means applies to said driving means a driving signal in the form of a rectangular pulse having an amplitude of binary or ternary value, based on combining the plurality of rectangular pulse signals.

3. An oscillator device according to claim 1, wherein said oscillation system is configured to have a reference oscillation mode which is a natural oscillation mode having a reference frequency, and an integral-multiple oscillation mode which is a natural oscillation mode having a frequency which is n-fold the reference frequency where n is an integer.

4. An oscillator device according to claim 1, wherein said oscillation system includes a plurality of oscillators configured to oscillate, a plurality of torsion springs disposed along a co-axis coupling said plurality of oscillators in series, and a supporting member configured to support a portion of said plurality of torsion springs.

5. An oscillator device according to claim 1, wherein said oscillation system includes one oscillator configured to oscillate in circumferential directions about different axes.

6. An oscillator device according to claim 1, wherein said drive control means applies to said driving means a driving signal of rectangular pulse having an amplitude of binary value based on combining the plurality of rectangular pulse signals, and wherein said drive control means applies to said driving means a driving signal having a frequency component sufficiently far away from a natural frequency when the amplitude should be made zero.

7. An oscillator device according to claim 1, wherein said drive control means generates a plurality of rectangular pulse signals corresponding to sinusoidal waves having frequencies of the natural oscillation modes, respectively, while taking an amplitude, a pulse width and a phase difference of rectangular pulses of the rectangular pulse signals as parameters, wherein said drive control means performs Fourier series expansion of a plurality of rectangular pulse signals as presented by the parameters and generates an equation including a sinusoidal wave by erasing a term of a frequency other than the frequency of the natural oscillation mode, among the terms expressed by the Fourier series expansion, to thereby determine the parameters based on the amplitude and phase of the equation, and wherein said drive control means drives the oscillation system in accordance with a driving signal which is based on the sum of the rectangular pulse signals determined by the parameters.

8. An oscillator device according to claim 1, further comprising detecting means configured to detect a state of oscillation of said oscillator.

9. An oscillator device according to claim 8, wherein said drive control means calculates a controlled amount of the driving signal based on a signal from said detecting means and generates the driving signal.

10. An optical deflecting device, comprising:
a light source configured to generate a light beam; and
an oscillator device as recited in claim 1 and having a light deflecting element formed on said at least one oscillator.

11. An optical equipment, comprising:
an optical deflecting device as recited in claim 10; and
a target object;
wherein said optical deflecting device is configured to deflect light from said light source and to direct at least a portion of the light onto said target object.

12. A drive control method for an oscillation system including at least one oscillator configured to oscillate, the oscillation system having a plurality of natural oscillation modes with a plurality of frequencies which frequencies are mutually in a relationship of integral-number ratio, said method comprising:
generating a plurality of rectangular pulse signals corresponding to sinusoidal waves having frequencies of the natural oscillation modes, respectively, while taking an amplitude, a pulse width and a phase difference of rectangular pulses of the rectangular pulse signals as parameters;
performing Fourier series expansion of a plurality of rectangular pulse signals as presented by the parameters and generating an equation including a sinusoidal wave, by erasing a term of a frequency other than the frequency of the natural oscillation mode, among the terms expressed by the Fourier series expansion;
determining the parameters based on the amplitude and phase of the equation; and
driving the oscillation system in accordance with a driving signal which is based on the sum of the rectangular pulse signals determined by the parameters.
